(19) United States
(12) Patent Application Publication
(10) Pub. No.: US 2012/0257343 A1
(43) Pub. Date: Oct. 11, 2012

(54) CONDUCTIVE METAL MICRO-PILLARS FOR ENHANCED ELECTRICAL INTERCONNECTION

(75) Inventors: Rabindra N. Das, Vestal, NY (US); Konstantinos I. Papathomas, Endicott, NY (US); Mark D. Poliks, Vestal, NY (US); Voya R. Markovich, Endwell, NY (US)

(73) Assignee: ENDICOTT INTERCONNECT TECHNOLOGIES, INC., Endicott, NY (US)

(21) Appl. No.: 13/082,502

(22) Filed: Apr. 8, 2011

(51) Int. Cl. G06F 1/16; H05K 3/00; H05K 1/09; G03F 7/20; H01B 1/02; B82Y 99/00

(52) U.S. Cl. 361/679.4; 430/311; 252/514; 427/97.1; 174/257; 977/932

(57) ABSTRACT

A method of forming a circuitized substrate for use in electronic packages. A substrate layer is provided that has a copper pad on a surface. A conductive seed layer and a photoresist layer are placed on the surface. The photoresist is developed and conductive material is placed within the developed features and a second conductive material placed on the first conductive material. The photoresist and conductive seed layer are removed to leave a micro-pillar array. The joining and lamination of two circuitized substrate layers utilizes the micro-pillar array for the electrical connection of the circuitized substrate layers.

### FIELD OF INVENTION

The present invention relates to the preparation of electrical interconnects between circuit boards and, more specifically, to an electrical interconnection process, optionally using an electrically conductive adhesive (ECA) or paste, that enhances the Z-axis electrical connection between layers, and to a structure wherein conductive pillars or spikes are utilized as a contact point between circuitized substrates.

### BACKGROUND OF THE INVENTION

The needs of the semiconductor marketplace continue to drive density into semiconductor packages. Traditionally, greater wiring densities have been achieved by reducing the dimensions of vias, lines, and spaces, increasing the number of wiring layers, and utilizing blind and buried vias. However, each of these approaches (e.g., those related to drilling and plating of high aspect ratio vias, reduced conductance of narrow circuit lines, and increased cost of fabrication related to additional wiring layers) includes inherent limitations.

PCBs, chip carriers and related products used in many of today's technologies must include multiple circuits in a minimum volume or space. Typically, such products comprise a stack of layers of signal, ground and/or power planes separated from each other by at least one layer of electrically insulating dielectric material. The circuit lines or pads (e.g., those of the signal planes) are often in electrical contact with each other by plated holes passing through the dielectric layers. The plated holes are often referred to as vias if internally located, blind vias if extending a predetermined depth within the board from an external surface, or plated-thru-holes (PTHs) if extending substantially through the board's full thickness. The term thru-hole as used herein is meant to include all three types of such board openings.

Complexity of these products has increased significantly in recent years. PCBs for mainframe computers may have as many as seventy-two layers of circuitry or more, with the complete stack having a thickness of as much as about 0.800 inch (800 mils). These boards are typically designed with three or five mil wide signal lines and twelve mil diameter thru-holes. Increased circuit densification requirements seek to reduce signal lines to a width of two mils or less and thru-hole diameters to two mils or less. Many known commercial procedures, especially those of the nature described herein, are incapable of economically forming these dimensions now desired by the industry.

Such processes typically comprise fabrication of separate innerlayer circuits (circuitized layers), which are formed by coating a photosensitive layer or film over the copper layer of a copper clad innerlayer base material. The photosensitive coating is imaged and developed and the exposed copper is etched to form conductor lines. After etching, the photosensitive film is stripped from the copper, leaving the circuit pattern on the surface of the innerlayer base material. This processing is also referred to as photolithographic processing in the PCB art and further description is not deemed necessary.

After the formation of the individual innerlayer circuits, a multilayer stack is formed by preparing a lay-up of core innerlayers, ground planes, power planes, etc., typically separated from each other by a dielectric prepreg comprising a layer of glass (typically fiberglass) cloth impregnated with a partially cured material, typically a B-stage epoxy resin. The top and bottom outer layers of the stack usually comprise copper clad, glass-filled epoxy planar substrates with the copper cladding comprising the exterior surfaces of the stack. The stack is laminated to form a monolithic structure using heat and pressure to fully cure the B-stage resin. The stack so formed typically has metal (usually copper) cladding on both of its exterior surfaces. Exterior circuit layers are formed in the copper cladding using procedures similar to the procedures used to form the innerlayer circuits. A photosensitive film is applied to the copper cladding. The coating is exposed to patterned activating radiation and developed. An etchant is then used to remove copper bared by the development of the photosensitive film. Finally, the remaining photosensitive film is removed to provide the exterior circuit layers.

The aforementioned thru-holes (also often referred to as interconnects) are used in many such substrates to electrically connect individual circuit layers within the structure to each other and to the outer surfaces. The thru-holes typically pass through all or a portion of the stack. Thru-holes are generally formed prior to the formation of circuits on the exterior surfaces by drilling holes through the stack at appropriate locations. Following several pre-treatment steps, the walls of the holes are catalyzed by contact with a plating catalyst and metallized, typically by contact with an electroless or electrolytic copper plating solution to form conductive pathways between circuit layers. Following formation of the conductive thru-holes, exterior circuits, or outerlayers, are formed using the procedure described above.

Current commercially available electrically conductive adhesives (ECAs) or paste makes it necessary to load a higher metal for sintering in these pastes, but a highly loaded system has no mechanical strength. However, even when a low metal loading system is used, no sintering occurs even at very high temperatures (e.g., 300° C.). Therefore, it is advantageous to have a conducting paste that shows a good electrical yield as well as low contact resistance in order to allow adhesion between the substrate interconnections. This can be achieved by using a solvent free paste, such as described hereinbelow in the present invention, which paste can be cured and completely sintered at or below 200° C.

### DISCUSSION OF RELATED ART

U.S. Pat. No. 7,670,874, issued Mar. 2, 2010, to Trezza, for PLATED PILLAR PACKAGE FORMATION, discloses a method involving plating pillars of electrically conductive material up from a seed layer located on a substrate, surrounding the pillars with a fill material so that the pillars and fill material collectively define a first package, and removing the substrate from the first package.

U.S. Pat. Nos. 7,135,777 and 7,468,558, issued Nov. 14, 2006 and Dec. 23, 2008, respectively, to Bakir et al., for DEVICES HAVING COMPLIANT WAFER-LEVEL INPUT/OUTPUT INTERCONNECTIONS AND PACKAGES USING PILLARS AND METHODS OF FABRICATION THEREOF, discloses a device having one or more of the following: an input/output (I/O) interconnect system, an optical I/O interconnect, an electrical I/O interconnect, a radio frequency I/O interconnect, are disclosed. A representative I/O interconnect system includes a first substrate and a second substrate. The first substrate includes a compliant pillar vertically extending from the first substrate. The compliant pillar is constructed a first material. The second substrate includes a compliant socket adapted to receive the compliant pillar. The compliant socket is constructed of a second material.

U.S. Pat. No. 6,395,633, issued May 28, 2002, to Chenget al., for METHOD OF FORMING MICRO-VIA, discloses a method of forming a micro-via, for fabrication and design of a layout of a circuit board. A patterned conductive wiring layer is formed on the substrate. A copper layer is plated onto the substrate and the conductive wiring layer. A photoresist layer is formed on the copper layer. A part of the photoresist layer is removed to expose a part of the copper layer. Using the copper layer as a seed layer, a conductive pillar is formed on the exposed part of the copper layer. The photoresist layer is removed. The exposed plated copper layer is removed. An insulation layer is formed on surfaces of the substrate and the conductive pillar. A part of the insulation layer is removed to expose the conductive pillar. A patterned conductive wiring layer is formed on the conductive pillar.

U.S. Pat. No. 6,669,079, issued Dec. 30, 2003, to Li, et al. for CONDUCTIVE PASTE AND SEMICONDUCTOR COMPONENT HAVING CONDUCTIVE BUMPS MADE FROM THE CONDUCTIVE PASTE discloses a conductive paste to make conductive bumps on a substrate. The conductive paste is formed by combining a tin alloy with a flux composition containing an aromatic carboxylic acid fluxing agent and a solvent. The conductive paste is disposed on underbump metallization layers and reflowed to form the conductive bumps. This conductive paste uses a tin alloy and does not connect interconnects on a micro scale level. In addition, the paste is not made by mixing two different conducting pastes, where each paste maintains its own micro level individual rich region in the mixed paste even after final curing.

United States Published Patent Application No. 2009/0162557 published Jun. 25, 2009 by Lu, et al. for NANOSCALE METAL PASTE FOR INTERCONNECT AND METHOD OF USE describes a paste including metal or metal alloy particles (which are preferably silver or silver alloy), a dispersant material, and a binder to form an electrical, mechanical or thermal interconnect between a device and a substrate. By using nanoscale particles (i.e., those which are less than 500 nm in size and most preferably less than 100 nm in size), the metal or metal alloy particles can be sintered at a low temperature to form a layer that allows good electrical, thermal and mechanical bonding. The metal or metal alloy layer can enable usage at a high temperature such as would be desired for SiC, GaN, or diamond wide bandgap devices.

United States Published Patent Application No. 2005/0093164 published May 5, 2005 by Standing for PASTE FOR FORMING AN INTERCONNECT AND INTERCONNECT FORMED FROM THE PASTE describes a paste that includes a mixture of binder particles, filler particles and flux material. The binder particles have a melting temperature lower than that of the filler particles. The proportion of the binder particles and the filler particles is selected so that, when heat is applied to melt the binder particles, the shape of the paste as deposited is substantially retained thereby, allowing for the paste to be used for forming interconnect structures. The present invention does not contain binder particles or any parts that include tin-silver solder, such as prior art binder materials that contain 95.5% Sn, 3.8% Ag, and 0.7% Cu by weight.

The previously disclosed United States issued patents and published patent applications listed above deal with methods of forming electrically conducting micro-pillars and pastes, but none of the methods is similar to the present invention that forms a conductive micro-pillar for improved interconnection between substrate layers, optionally having a solvent free paste that can be cured and completely sintered at or below 200° C.

When performing the process of joining connections between substrate layer interconnects, a conductive micro-pillar structure, optionally utilizing conducting paste, is one that has a good electrical yield and a reduced instance of resistive opens between substrate layers, such as the present invention.

It is therefore an object of the invention to provide an interconnect structure that enhances the electrical and physical contact of joining substrate Z-interconnect structures.

It is also an object of this invention to use a micro-pillar structure to enhance circuit board interfacial connections between adjacent circuit boards.

It is also an object of this invention to utilize the micro-pillar structure within a blind clearance hole on a power, ground, or signal substrate plane to enhance the electrical connection of interlayer communications and limit resistive opens or failure risk.

It is a further an object of this invention to provide an ECA having a solvent free paste that can be cured and completely sintered at or below 200° C.

### SUMMARY OF THE INVENTION

According to the present invention, there is provided a structure and method including a first circuitized substrate layer having a first surface containing a copper interconnect pad having a first plurality of micro-pillars disposed on a surface and a second circuitized substrate layer having a second surface containing a copper interconnect pad having a second plurality of micro-pillars disposed on a surface and electrically connecting said micro-pillars of said first circuitized substrate layer and said second circuitized substrate layer for Z-axis interconnects of circuitized substrates.

### BRIEF DESCRIPTION OF THE DRAWINGS

A complete understanding of the present invention may be obtained by reference to the accompanying drawings, when considered in conjunction with the subsequent, detailed description, in which:

FIG. 1a shows a joining process of two substrates;

FIG. 1b illustrates the joined substrates of FIG. 1a;

FIG. 2a shows a joining process of two substrates and a power plane;

FIG. 2b illustrates the joined substrates of FIG. 2a;

FIG. 3a shows a joining process of two substrates utilizing paste;

FIG. 3b illustrates the joined substrates of FIG. 3a;

FIGS. 4a-4e illustrate a process of creating micro-pillars on a substrate;

FIGS. 5a-5e illustrate an alternate process for creating micro-pillars on a substrate;

FIGS. 6 shows a type of micro-pillar used for interconnections of a substrate;

FIGS. 7a and 7b are perspective views of conductive pillars on a substrate;

FIGS. 8a and 8b, taken together, are a representation of the inventive method to form an embodiment of the conducting paste for interconnects; and

FIG. 9 represents an information handling system according to one aspect of the invention, which is capable of utilizing one or more of the electronic packages taught herein.

### DETAILED DESCRIPTION OF THE PREFERRED EMBODIMENT

For a better understanding of the present invention, together with other and further objects, advantages, and capabilities thereof, reference is made to the following disclosure and appended claims in connection with the above-described drawings. The present invention is further described with reference to the accompanying figures where like reference numbers correspond to the same elements.

By the term “circuitized substrate” as used herein is meant a substrate structure having at least one (and preferably more) dielectric layer and at least one external conductive layer positioned on the dielectric layer and including a plurality of conductor pads as part thereof. The conductive layers preferably serve to conduct electrical signals, including those of the high frequency type, and is preferably comprised of suitable metals such as copper, again, as this is the thrust of this application.

By the term “electroplating” as used herein is meant a process by which a metal in its ionic form is supplied with electrons to form a non-ionic coating on a desired substrate. The most common system involves: a chemical solution which contains the ionic form of the metal, an anode (positively charged) which may consist of the metal being plated (a soluble anode) or an insoluble anode (usually carbon, platinum, titanium, lead, or steel), and finally, a cathode (negatively charged) where electrons are supplied to produce a film of non-ionic metal.

By the term “electroless plating” (also known as chemical or auto-catalytic plating) as used herein is meant a non-galvanic type of plating method that involves several simultaneous reactions in an aqueous solution, which occur without the use of external electrical power. The reaction is accomplished when hydrogen is released by a reducing agent, normally sodium hypophosphite, and oxidized thus producing a negative charge on the surface of the part.

By the term “electronic package” as used herein is meant a circuitized substrate assembly as taught herein having one or more ICs (e.g., semiconductor chips) positioned thereon and electrically coupled thereto. In a multi-chip electronic package, for example, a processor, a memory device and a logic chip may be utilized and oriented in a manner designed for minimizing the limitation of system operational speed caused by long connection paths. Some examples of such packages, including those with a single chip or a plurality thereof, are also referred to in the art as chip carriers.

By the term “etch” and “etching” as used herein is meant a process by where a surface of a substrate is either selectively etched using a photoresist or covered by a mask prior to plasma treating, both methods are meant to transfer an image onto the substrate for subsequent further processing.

The term “micro pillar” is the structure grown from a base metal surface in such a way that that the peak height of the structure is equal or less than the z-joint height. Structure consists of single metal or multiple metals deposited by layer after layer metallization. The base metal pad can contain single or multiple micro pillars. Micro pillars achieve physical, chemical, mechanical and/or metallic bonding during lamination.

By the term “information handling system” as used herein is meant any instrumentality or aggregate of instrumentalities primarily designed to compute, classify, process, transmit, receive, retrieve, originate, switch, store, display, manifest, measure, detect, record, reproduce, handle or utilize any form of information, intelligence or data for business, scientific, control or other purposes. Examples include personal computers and larger processors such as computer servers and mainframes. Such products are well known in the art and are also known to include PCBs and other forms of circuitized substrates as part thereof, some including several such components depending on the operational requirements thereof.

By the term “laser ablation” as used herein is meant the process of removing material from a solid surface by irradiating it with a laser beam. At low laser flux, the material is heated by the absorbed laser energy and evaporates or sublimes. At high laser flux, the material is typically converted to a plasma. The term laser ablation as used herein refers to removing material with a pulsed laser as well as ablating material with a continuous wave laser beam if the laser intensity is high enough.

By the term “thru-hole” as used herein to define an electrically conductive structure formed within a circuitized substrate as defined herein and is meant to include three different types of electrically conductive elements. It is known in multilayered PCB's and chip carriers to provide various conductive interconnections between various conductive layers of the PCB and carrier. For some applications, it is desired that electrical connection be made with almost if not all of the conductive layers. In such a case, thru-holes are typically provided through the entire thickness of the board, in which case these are often also referred to as “plated thru holes” or PTHS. For other applications, it is often desired to also provide electrical connection between the circuitry on one face of the substrate to a depth of only one or more of the inner circuit layers. These are referred to as “blind vias”, which pass only part way through (into) the substrate. In still another case, such multilayered substrates often require internal connections (“vias”) which are located entirely within the substrate and covered by external layering, including both dielectric and conductive. Such internal “vias”, also referred to as “buried vias”, may be formed within a first circuitized substrate which is then bonded to other substrates and/or dielectric and/or conductive layers to form the final, multilayered embodiment. Therefore, for purposes of this application, the term “thru hole” is meant to include all three types of such electrically conductive openings.

Z-axis interconnections are important for high density and high performance packaging. There needs to be 100% yield in order to make interconnect operational. Current technology has several interface issues that sometimes produce resistive opens, and failure of the part. Rework of a Z-interconnect failure is a complex task.

In the present invention, the inventive design for Z-axis interconnections results in reduced substrate-to-substrate interface issues and produces a robust Z-axis interconnection. The interconnect design consists of multiple Cu—Sn, Cu—Sn—Au, Cu—Sn—Pb, or Cu—Sn—Pb—Au based micro-pillars grown on top of a base Cu pad or plane. These micro-pillars form multiple interconnections among the Cu pads after two or more subcomposite elements are laminated. Multiple interconnections of the contact point create an interlock structure and can reduce the failure risk of a resistive open circuit.

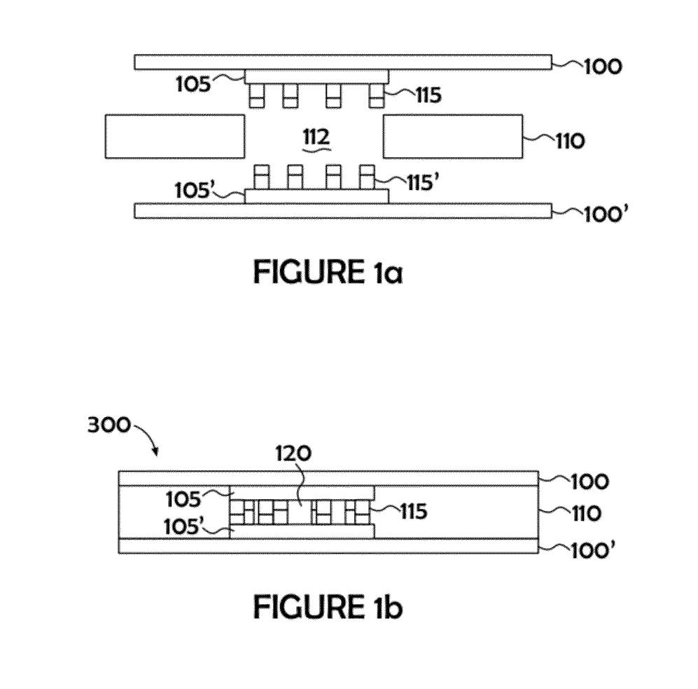

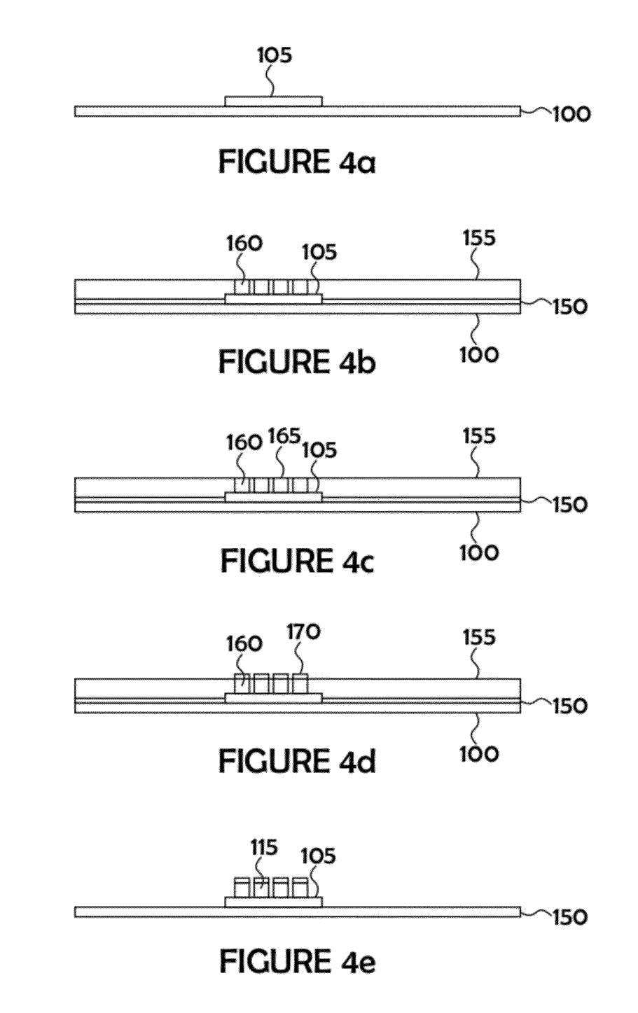

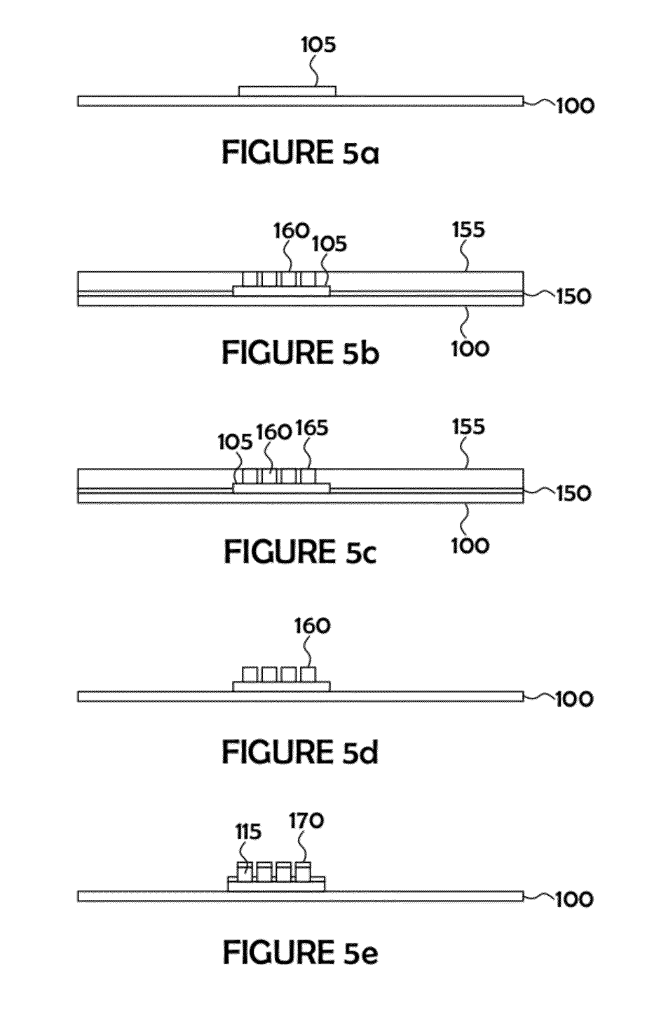

FIG. 1a represents a joining process of two substrates 100, 100′ using micro-pillar arrays 115, 115′ that are grown on top of a base copper pads 105, 105′. The construction of the micro-pillars 115 is described in FIGS. 4 and 5. The substrates 100, 100′ are laminated together with a drilled 112 pre-preg layer 110 positioned between the substrates 100, 100′ and encompassing the micro-pillar arrays 115, 115′.

FIG. 1b shows, in this embodiment, that the resin from the prepreg 110 will flow into the void space 120 remaining after the micro-pillars 115, 115′ have made contact. Not shown in this and subsequent FIGURES is the circuitry and layers of PCB 300 that are connected to the copper pads 105, 105′. The electronic package technology is known and not discussed further. FIG. 1b shows two possible electrical contact areas. One is between micro pillar (115, 115′) and opposing pads (105, 105′). The second is a side wall connection among the micro pillars (115, 115′). Each electrical contact area can have physical, chemical, mechanical, metallic, and/or combination bonding. Resin flow from prepreg during lamination will stabilize those electrical contact areas and make the entire electrical joint robust.

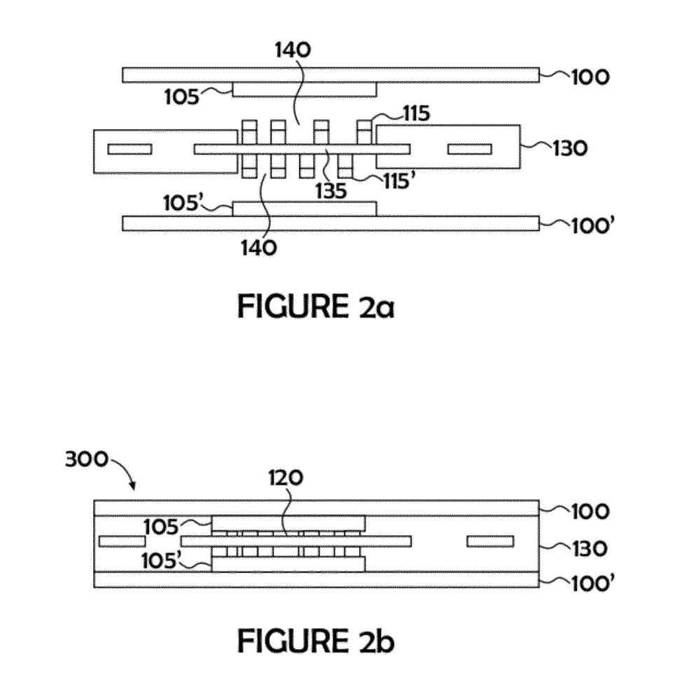

FIG. 2a represents a joining process of two substrates 100, 100′ having copper pads 105, 105′. A power plane 130 containing micro-pillar arrays 115, 115′ is placed between the substrates 100, 100′. The micro-pillar arrays 115, 115′ are grown in clearance holes 140 that expose the core copper plane 135, and are located on both sides of power plane 130. Again, the construction of the micro-pillars 115, 115′ is described in FIGS. 4 and 5. The substrates 100, 100′ are laminated together with a power plane 130 positioned between the substrates 100, 100′ and encapsulating the micro-pillar arrays 115. Alternatively, reference number 130 can represent a dielectric sandwiched between metal layers (e.g., Cu-polyimide-Cu). Here top and bottom Cu pads 130 are connected with plated though holes to produce micro pillars 115, 115′.

FIG. 2b shows, in this embodiment, that the resin from the power plane 130 will flow into the void space 120 remaining in clearance holes 140 after the micro-pillars 115, 115′ have made contact. FIG. 2b shows one possible electrical connection between micro pillars 115 and an opposing pad 105.

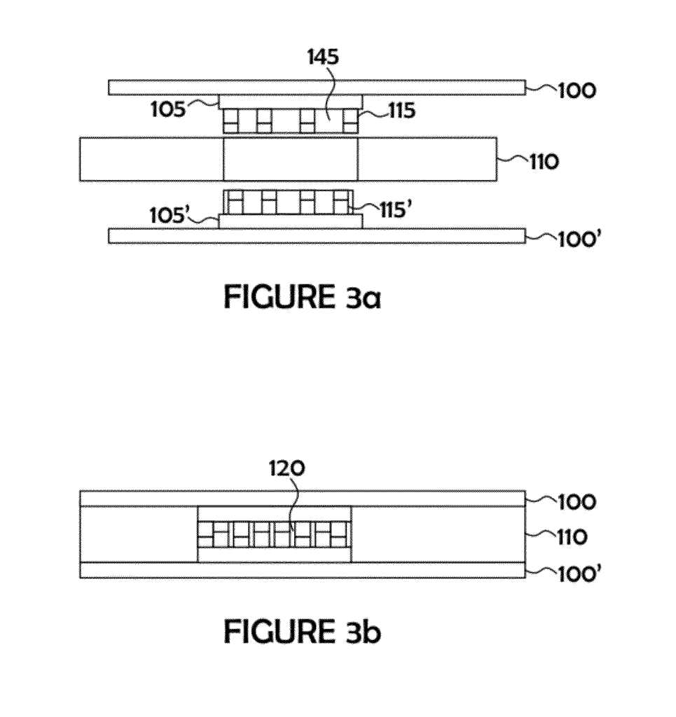

FIG. 3a represents a joining process similar to FIGURE la of two substrates 100, 100′ using micro-pillar arrays 115, 115′ that are grown on top of a base copper pads 105, 105′. Prior to lamination, an ECA or paste 145 is deposited on the micro-pillar arrays 115, 115′ to enhance the connection process between the two substrates 100, 100′. The substrates 100, 100′ are then laminated together with a drilled 112 pre-preg layer 110 positioned between the substrates 100, 100′ and encompassing the conductive paste 145 covered micro-pillar arrays 115, 115′.

FIG. 3b shows, in this embodiment, conductive paste 145 filling in the void space 120 remaining after the micro-pillars 115, 115′ have made contact. There are several electrical contact areas. A paste connection can exist between opposing Cu pads (electrical conduction path:105-145-105′). A paste connection can exist between a micro pillar and an opposing pad (electrical conduction path:115-145-105′). Paste connections can also exist between micro pillars (electrical conduction path :115-145-115′).

Referring to FIGS. 1b and 3b, it is also possible that the peak heights of micro pillars are less than joint heights. In these cases, micro pillars can touch each other (115-115′) (FIG. 1b) and/or micro pillars can connect with each other by conductive paste to establish an electrical connection.

In FIGS. 4a-4e and 5a-5e, there are shown two embodiments of the process steps for creating micro-pillars 115, 115′. Beginning with FIG. 4a, there is shown a substrate 100 having a base copper pad 105. A thin layer of seed copper 150 is sputtered on to the substrate 100 using known processes, after which a layer of photoresist 155 is applied and then developed, creating the openings 160 that will form the support for micro-pillars 115.

FIG. 4c shows the openings 160 having been electroplated with copper to create the micro-pillars 115, sometimes referred to in the art as spikes. FIG. 4d adds an Sn or Sn—Pb or Sn—Au or Sn—Ag top 170, either by plating or an immersion process, to the copper pillar 165. Strip resist 155 and etch to remove sputtered Cu or seed layer 150 as seen in FIG. 4e to complete one embodiment of substrate 100 containing micro-pillars 115, 115′.

Referring now to FIGS. 5a-5e, there is shown a second embodiment of the process steps for creating micro-pillars 115 wherein substrate 100 has a base copper pad 105. A thin layer of seed copper 150 is sputtered on to the substrate 100 using known processes, after which a layer of photoresist 155 is applied and then developed, creating the openings 160 that will form the support for micro-pillars 115. FIG. 5c shows the openings 160 having been electroplated with copper to create the micro-pillars 115, sometimes referred to in the art as spikes. FIG. 5d removes resist 155 and etch to remove sputtered Cu or seed layer 150. As seen in FIG. 5e, there is added an Sn or Sn—Pb or Sn—Au or Sn—Ag top 170, either by plating or an immersion process, to the copper pillar 165 to complete one embodiment of substrate 100 containing micro-pillars 115, 115′.

The purpose of an Sn or Sn—Pb or Sn—Au or Sn—Ag top is to melt and interdiffuse with each other during lamination to produce more reliable joints. For example, Sn or Sn—Pb or Sn—Au or Sn—Ag top 115′ will interdiffuse with micro pillar 105 in FIG. 1b.

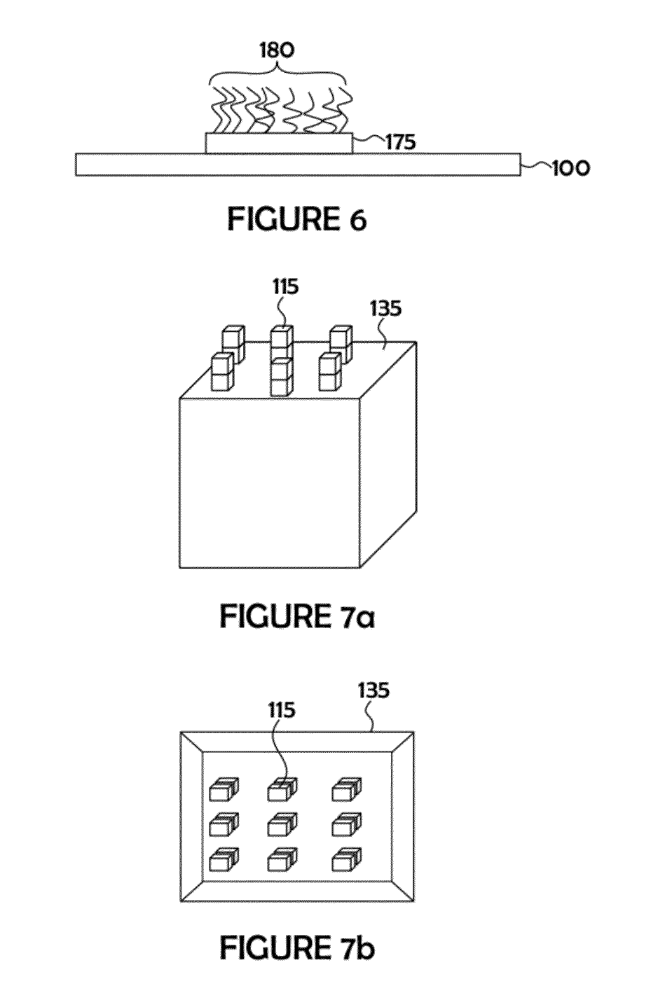

FIG. 6 illustrates more embodiments of micro-pillars 115, 115′ of the current invention whereby conductive carbon, metal, mixtures of metals or alloys, nanotube, nanowire, nanofiber, micro fiber, micro tube, microwire can be grown or placed 180 on top of a gold finished surface 175 for other interconnection applications.

FIGS. 7a-7b are perspective views of micro-pillars 115, 115′ on a core copper plane 135 of a power plane 130, or on a base copper pad 105 of substrate 100.

The conductive paste 145 of FIG. 3 uses nanoparticles. Nanoparticles generally refer to the class of ultra fine metal particles with a physical structure or crystalline form that measures less than 100 nm in size. They can be 3D (block), 2D (plate), or 1D (tube or wire) structures. In general, nanoparticle-filled conductive adhesives are defined as adhesives containing at least some percentage of nanostructures (1D, 2D, and/or 3D) that enhance the overall electrical conductivity or sintering behavior of the adhesives. Conductivity is achieved through metal-metal bonding. Increasing the density of particles increases the probability of metal-metal contact. Each contact spot possesses a contact resistance. For microparticles, the density of particles is much less than for nanoparticles. In the case of a nano-micro mixture, the micro-scale particles can maintain a low contact resistance, whereas nano-scale particles can increase the number of particle contacts. Nano and micro particle mixtures can be nanoparticle-microparticle, nanoplate (2D)-microparticle, nanotube (1D)-microparticle, or any combination of the aforementioned cases. A low melting point (LMP) filler melts and reduces inter-particle resistance. Hence, conductive adhesives can be categorized as nano, micro, nano-micro, or LMP based systems. So electrical connections through paste in FIG. 3b can be particle-particle contact and or by nano particle sintering and/or by LMP melting.

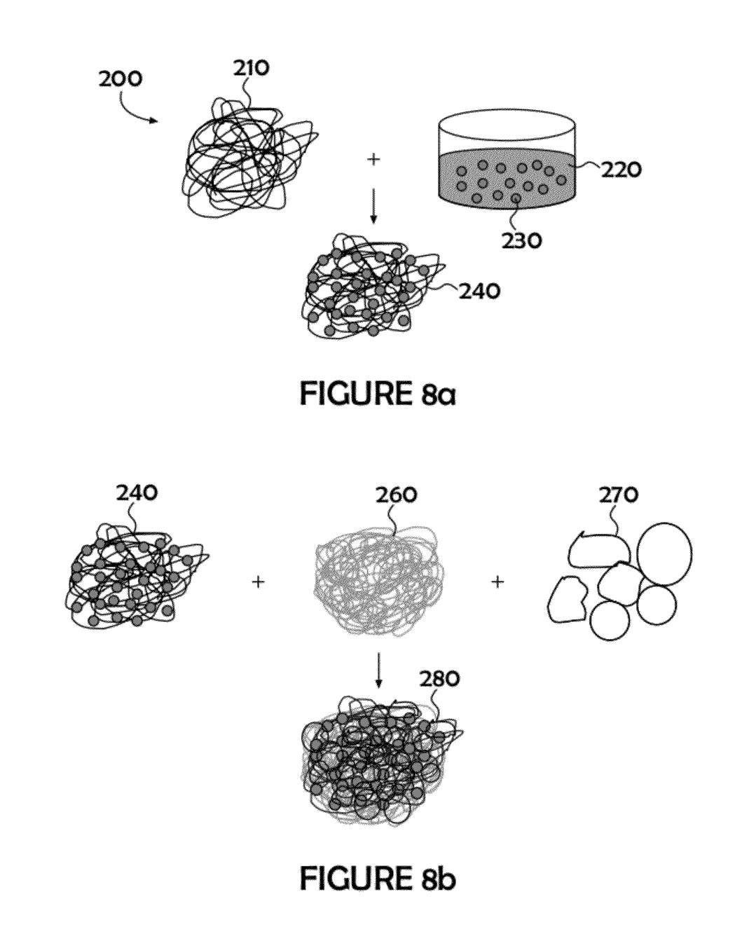

With reference to FIGS. 8a and 8b, the method of forming, nano-micro paste 200 is shown. A resin or part of a resin component 210 is mixed with silver or any other nanoparticle solution (Au, Pt, etc.) 230 in a low boiling temperature solvent 220. The solvent 220 is then evaporated, leaving a mixture containing resin and embedded nanoparticles 240. The resin with embedded nanoparticles 240 is mixed with another component, such as an anhydride or cross-linking agent 260, and dry micro-powder 270, to form a nano-micro paste 280. If necessary, a catalyst can be added to nano-micro paste 280. This kind of paste can maintain very fine nanoparticles in the paste. In general, 5 nm Ag nanoparticles sinter at room temperature to form larger particles. In nano-micro paste 280, 5 nm particles are stable at room temperature and can utilize the low temperature sintering impact of the paste during the curing processing. The embedding of nano and micro particles is such that the nanoparticles will not agglomerate during paste formulation and will maintain a low temperature sintering mechanism during final paste curing process.

Sintering temperature can be reduced greatly when the particle size is decreased to 10-15 nanometers. Conductivity measurements show that the resistance for 10-15 nm particles is 85% lower when cured at 200° C. than it is when cured at 150° C. A variety of nanoparticles ranging from 10 nm to 80 nm was used to modify micro adhesive composites. Particle size has a direct effect on particle diffusion/sintering. Sintering of a system containing 10-15 nm particles starts at 200° C. Nanoparticles are sintered, but some microparticles remain un-sintered. The sintering process completes at 240° C., when all particles are sintered. In the nano micro composites, the main components are a mixture of nanoparticles and microparticles. The nanoparticles may contact with adjacent ones, but the nano aggregation lengths are short, less than one order of magnitude of the microparticle diameter, on average. As the sintering temperature increases, particle diffusion becomes more and more obvious. The aggregation length becomes much longer, resulting in the formation of one-dimensional jointed particle assemblies developing into a smooth continuous network.

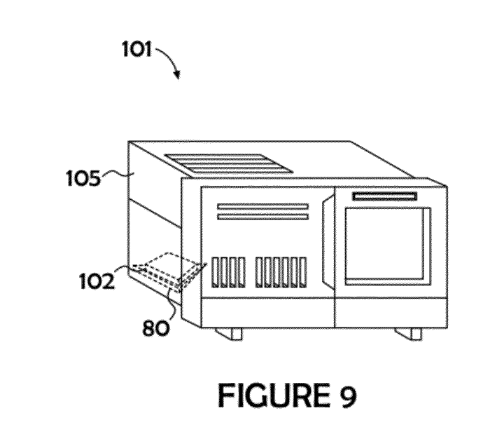

As stated, each circuitized substrate formed in accordance with the teachings herein may be utilized within a larger substrate of known type such as a PCB, chip carrier or the like. FIG. 1b illustrates one of these larger components, PCB 300, which may be positioned within and electrically coupled to an information handling system (IHS) 101 as shown in FIG. 9, which may be in the form of a personal computer, mainframe, computer server, etc. PCB 300, as shown, is typically electrically coupled to other PCBs 300 to form a processing assemblage within IHS 101. For example, one or more circuitized substrates 100, each forming a particular circuitized core (e.g., a power core) within PCB 300, may be utilized to afford the PCB the highly advantageous teachings of the invention. Or, as stated, the entire PCB may comprise circuitized substrates as taught here. Many different combinations are thus possible.

In FIG. 9, there is shown an information handling system 101 in accordance with one embodiment of the invention. IHS 101 may comprise a personal computer, mainframe computer, computer server, or the like, several types of which are well known in the art. IHS 101, as taught herein, may include one or more of the electrical assemblies as shown in FIG. 1b, including PCB 300, these being represented by reference numeral 102 in FIG. 9. This completed assembly, not shown, may be mounted on a still larger PCB or other substrate 80, one example being a motherboard of much larger size, should such a board be required. These components are not shown because they are enclosed within and thus behind a suitable housing 105 designed to accommodate the various electrical and other components which form part of system 101. PCB 300 may instead comprise such a motherboard in IHS 101 and thus include additional electrical assemblies, including additional printed circuit cards mounted thereon, such additional cards in turn also possibly including additional electronic components as part thereof. It is thus seen and to be understood that the electrical assemblies made in accordance with the unique teachings herein may be utilized in several various structures as part of a much larger system, such as IHS 101. Further description is not believed necessary.

Since other combinations, modifications and changes varied to fit particular operating requirements and environments will be apparent to those skilled in the art, the invention is not considered limited to the chosen preferred embodiments for purposes of this disclosure, but covers all changes and modifications which do not constitute departures from the true spirit and scope of this invention.

Having thus described the invention, what is desired to be protected by Letters Patent is presented in the subsequently appended claims.

What is claimed is:

1. A method of forming a circuitized substrate for use in electronic packages, the steps comprising:
a) providing a substrate layer having an upper surface and a lower surface;
b) disposing a copper layer on said upper surface of said substrate layer;
c) forming an interconnect pad on said copper layer;
d) disposing a conductive seed layer on said upper surface of said substrate layer;
e) disposing a photoresist layer on said conductive seed layer;
f) developing electrical features on said photoresist layer;
g) disposing a first conductive material within said features of said photoresist layer;
h) disposing a second conductive material on said first conductive material; and
i) removing said photoresist layer and said conductive seed layer.

2. The method of forming a circuitized substrate as in claim 1, wherein said disposing step (h) and said removing step (i) are performed in reverse order.

3. The method of forming a circuitized substrate as in claim 1, wherein said first conductive material comprises an approximately 1-100 micron thick layer of copper.

4. The method of forming a circuitized substrate as in claim 1, wherein said second conductive material further comprises:
i) a tin solder material;
ii) a tin-lead solder material;
iii) a tin-gold solder material; and
iv) a tin-silver solder material.

5. A method of forming a circuitized substrate for use in electronic packages, the steps comprising:
a) providing a substrate layer having an upper surface and a lower surface;
b) disposing a copper layer on said upper surface of said substrate layer;
c) forming an interconnect pad on said copper layer;
d) disposing a conductive seed layer on said upper surface of said substrate layer; and
e) disposing an object on said conductive seed layer, said object selected from at least one of the group comprising: carbon, metal alloy, nanotube, nanowire, nanofiber, micro-fiber, micro-tube, and micro-wire.

6. The method of forming a circuitized substrate as in claim 5, wherein said conductive seed layer comprises gold.

7. A circuitized substrate for use in electronic packages comprising:
a first circuitized substrate layer having a first surface containing a copper interconnect pad having a first plurality of micro-pillars disposed on a surface thereof;
a second circuitized substrate layer having a second surface containing a copper interconnect pad having a second plurality of micro-pillars disposed on a surface thereof; and
said micro-pillars of said first circuitized substrate layer and said second circuitized substrate layer being aligned and interfaced prior to lamination.

8. The circuitized substrate of claim 7, wherein said micro-pillars comprise conductive metal.

9. The circuitized substrate of claim 7, further comprising a conductive paste disposed on said first plurality of micro-pillars and on said second plurality of micro-pillars.

10. A method of forming an electrically conducting adhesive (ECA) or paste mixture with high metal loading, the method comprising:
a) embedding a nanoparticle within a polymer constituent by adding a resin to a silver nanoparticle solution in a low temperature boiling solvent;
b) dissolving said polymer constituent containing said nanoparticles in said silver nanoparticle solution by evaporating said low temperature boiling solvent to form an embedded nanoparticle polymer;
c) combining said embedded nanoparticle polymer constituent with dry micro powder and an anhydride; and
d) mixing said embedded nanoparticle polymer, anhydride, and micro powder.

11. The method of claim 10, wherein said embedding step (a) further comprises adding micro particles with said nanoparticles in said solvent.

12. The method of claim 10, wherein said dissolving step (b) further comprises drying said solvent under a vacuum to evaporate said solvent.

13. An information handling system (IHS) comprising:
a housing; and
a circuitized substrate positioned substantially within said housing and including a first circuitized substrate layer having a first surface containing a copper interconnect pad having a first plurality of micro-pillars disposed on a surface and a second circuitized substrate layer having a second surface containing a copper interconnect pad having a second plurality of micro-pillars disposed on a surface and electrically connecting said micro-pillars of said first circuitized substrate layer and said second circuitized substrate layer for Z-axis interconnects of circuitized substrates.

14. The IHS of claim 13, wherein said IHS comprises an object selected from at least one of the group comprising: personal computer, mainframe computer, and computer server.
